(19) United States
(12) Patent Application Publication
(10) Pub. No.: US 2022/0028855 A1
(43) Pub. Date: Jan. 27, 2022

(54) SEMICONDUCTOR STRUCTURE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventors: Jisong JIN, Shanghai (CN); Abraham YOO, Shanghai (CN)

(21) Appl. No.: 17/347,816

(22) Filed: Jun. 15, 2021

(30) Foreign Application Priority Data
Jul. 24, 2020 (CN) 202010724356.5

(51) Int. Cl. H01L 27/088; H01L 29/267; H01L 29/10; H01L 21/8234

(52) U.S. Cl. CPC H01L 27/0886; H01L 21/823431; H01L 29/1054; H01L 29/267

(57) ABSTRACT

Semiconductor structures and fabrication methods are provided. The semiconductor structure includes a substrate including a first region; a first polarization layer on the first region; and a first gate structure on the first polarization layer. A material of the first polarization layer includes a semiconductor compound material containing first polarization atoms.

### CROSS-REFERENCE TO RELATED APPLICATION

This application claims the priority of Chinese Patent Application No. 202010724356.5, filed on Jul. 24, 2020, the content of which is incorporated by reference in its entirety.

### TECHNICAL FIELD

The present disclosure generally relates to the field of semiconductor manufacturing technology and, more particularly, relates to semiconductor structures and fabrication methods.

### BACKGROUND

Metal-oxide-semiconductor (MOS) transistors are one of the most important elements in modern integrated circuits (ICs). The basic structure of an MOS transistor includes a semiconductor substrate, and a gate structure on the surface of the semiconductor substrate. The gate structure includes a gate dielectric layer on the surface of the semiconductor substrate and a gate electrode layer on the surface of the gate dielectric layer. The MOS transistor also includes doped source/drain regions in the semiconductor substrate at both sides of the gate structure. The MOS transistors include PMOS transistors and NMOS transistors.

To meet the needs of the switching speeds of different transistors in the design of integrated circuits, it is necessary to form a plurality of transistors with different threshold voltages.

To reduce the adjustment of the threshold voltages of the PMOS transistor and the NMOS transistor, corresponding work function layers are formed on the surfaces of the gate dielectric layers of the PMOS transistor and the NMOS transistor. Among them, the work function layer of the PMOS transistor needs to have a higher work function, and the work function layer of the NMOS transistor needs to have a lower work function. In the PMOS transistor and the NMOS transistor, the materials of the work function layers are different to meet the needs of the respective work function adjustments.

However, the performance of the multi-threshold voltages fin field-effect transistors needs to be improved. The disclosed methods and semiconductor structures are directed to solve one or more problems set forth above and other problems in the art.

### SUMMARY

One aspect of the present disclosure provides a semiconductor structure, the semiconductor structure may include a substrate including a first region; a first polarization layer on the first region, wherein a material of the first polarization layer includes a semiconductor compound material containing first polarization atoms; and a first gate structure on the first polarization layer.

Optionally, the first polarization atoms include La atoms, Ce atoms, Nb atoms, Mg atoms, Sc atoms, Al atoms, or a combination thereof

Optionally, the material of the first polarization layer includes MₓSi_{y}O_{z}, MₓGe_{y}O_{w}, or MₓSi_{y}G_{z}O_{w}, wherein M is the first polarization atom.

Optionally, the substrate further includes a second region and a third region; and the semiconductor structure further includes a second polarization layer on the second region, wherein a material of the second polarization layer contains the first polarization atoms; a second gate structure on the second polarization layer; a first gate oxide layer on the third region; and a third gate structure on the first gate oxide layer.

Optionally, the semiconductor structure further includes a dielectric layer on the substrate. The dielectric layer includes a first opening, a second opening and a third opening; the first opening is on the first region; the second opening is on the second region; the third opening is on the third region; the first polarization layer and the first gate structure are formed in the first opening; the second polarization layer and the second gate structure are formed in the second opening; and the first gate oxide layer and the third gate structure are formed in the third opening.

Optionally, the first gate structure includes a first gate dielectric layer on the first polarization layer; and a first gate electrode layer on the first gate dielectric layer.

Optionally, the first gate structure further includes a first work function layer. The first work function layer is on the first gate dielectric layer and the first gate electrode layer is on the first work function layer.

Optionally, the second gate structure includes a second gate dielectric layer on the second polarization layer; and a second gate electrode layer on the second gate dielectric layer.

Optionally, the second gate structure further includes a second work function layer, wherein the second work function layer is on the second gate dielectric layer and the second gate electrode layer is on the second work function layer.

Optionally, the third gate structure includes a third gate dielectric layer on the first gate oxide layer; and a third gate electrode layer on the third gate dielectric layer.

Optionally, the third gate structure further includes a third work function layer. The third work function layer is on the third gate dielectric layer and the third gate electrode layer is on the third work function layer.

Optionally, a material of the first gate dielectric layer includes lanthanum oxide, cerium oxide, hafnium oxide, or a combination thereof.

Optionally, a material of the second gate dielectric layer includes lanthanum oxide, cerium oxide, hafnium oxide, or a combination thereof.

Optionally, a material of the third gate dielectric layer includes lanthanum oxide, cerium oxide, hafnium oxide, or a combination thereof.

Optionally, an atomic concentration of the first polarization atoms in the first polarization layer is in a range of approximately 2%-30%.

Optionally, an atomic concentration of the first polarization atoms in the second polarization layer is less than approximately 1%.

Another aspect of the present disclosure provides a method for fabricating a semiconductor structure. The method may include providing a substrate including a first region; forming a first polarization layer on the first region, wherein a material of the first polarization layer includes a semiconductor compound material containing first polarizations atoms; and forming a first gate structure on the first polarization layer.

Optionally, the substrate further includes a second region and a third region, and the method further includes forming a dielectric layer on the substrate, wherein the dielectric layer includes a first opening on the first region, a second opening on the second region and a third opening on the third region; forming the first polarization layer and the first gate structure in the first opening; forming a second polarization layer and a second gate structure in the second opening; and forming a third polarization layer and a third gate structure in the third opening.

Optionally, the method for forming the first polarization layer and the second polarization layer includes forming a first diffusion layer on the first region; forming a second gate oxide layer on the second region; forming a second diffusion layer on the second gate oxide layer; and annealing the first diffusion layer and the second diffusion layer to modify the second oxide layer into the second polarization layer and modify the first diffusion layer into the first polarization layer.

Optionally, the first gate structure includes a first gate dielectric layer on the first polarization layer and a first gate electrode layer on the first gate dielectric layer.

Thus, the technical solutions of the present disclosure may have the following advantages.

In the structure of the technical solutions of the present disclosure, the material of the first polarization layer located on the first region is a semiconductor compound material with first polarization atoms. The first polarized atoms in the first polarization layer may directly forms a corresponding salt compound with the semiconductor material such that the first polarization layer may have a higher threshold voltage. Thus. in the high threshold voltage environment, the adjustment range of each threshold voltage may be increased, the problem that different gates may have a same threshold voltage may be reduced, and the performance of the finally formed semiconductor structure may be effectively improved.

In the formation method of the technical solution of the present disclosure, a first polarization layer may be formed on the first region, and the material of the first polarization layer may be a semiconductor compound material having first polarization atoms. The first polarization atoms in the first polarized layer may directly form a corresponding salt compound with the semiconductor material such that the first polarization layer may have a higher threshold voltage. Thus, in the high threshold voltage environment, the adjustment range of each threshold voltage may be increased, the problem that different gates have a same threshold voltage may be reduced, and the performance of the finally formed semiconductor structure may be effectively improved.

### BRIEF DESCRIPTION OF THE DRAWINGS

The following drawings are merely examples for illustrative purposes according to various disclosed embodiments and are not intended to limit the scope of the present disclosure.

FIGS. 1-2 illustrate structures corresponding to certain stages during forming a semiconductor structure;

FIGS. 3-16 illustrate structures corresponding to certain stages during an exemplary fabrication process of a semiconductor structure consistent with various disclosed embodiments of the present disclosure; and

FIG. 17 illustrates an exemplary fabrication process of a semiconductor structure consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

With the further development of the semiconductor technology, the size of integrated circuit devices is getting smaller and smaller, and the distance between the corresponding adjacent fin structures is getting smaller and smaller. The number of stacked work function layers is usually adjusted to adjust the corresponding threshold voltages. However, due to the small distance between adjacent fin structures, it is difficult for the work function layer with many stacked layers to be filled between the adjacent fin structures. Thus, the threshold voltage is difficult to meet the requirements, and the performance of the final semiconductor structure may be adversely affected.

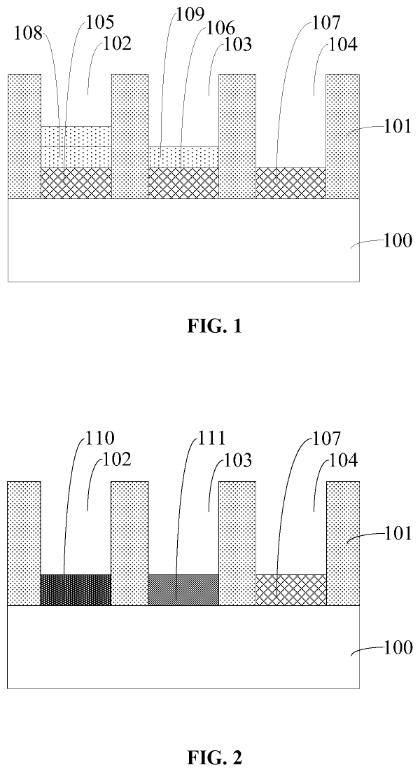

To solve the above-mentioned problems, a method for forming a semiconductor structure is proposed. FIGS. 1-2 illustrate structures corresponding to certain stages during the process for forming the semiconductor structure.

As shown in FIG. 1, the method includes providing a substrate 100 and forming a dielectric layer 101 on the substrate 100. The dielectric layer 101 includes a first opening 102, a second opening 103, and a third opening 104. The first opening 102, the second opening 103 and the third opening 104 expose the top surface of the substrate 100. Then, a first gate oxide layer 105, a second gate oxide layer 106, and a third gate oxide layer 107 are formed. The first gate oxide layer 105 is formed in the first opening 102, the second gate oxide layer 106 is formed in the second opening 103, and the third gate oxide layer 107 is formed in the third opening 104. Then, a first diffusion layer 108 and a second diffusion layer 109 are formed. The first diffusion layer 108 is formed on the first gate oxide layer 105 in the first opening 102, and the second diffusion layer 109 is formed on the second gate oxide layer 106 in the second opening 103.

Further, as shown in FIG. 2, the first diffusion layer 108 and the second diffusion layer 109 are annealed, and the first gate oxide layer 105 is modified into a first polarization layer 110, and the second gate oxide layer 106 is modified into a second polarization layer 111. The first polarization layer 110 and the second polarization layer 111 contain first polarization atoms.

In such an approach, the first polarization layer 110 and the second polarization layer 111 are formed, the first polarization layer 110 and the second polarization layer 111 have first polarization atoms. Using the chemical bonds formed between the first polarization atoms and the gate oxide layer and the number of stacked work function layers formed subsequently to jointly adjust the threshold voltages, the number of stacked work function layers is not the only factor that affects the threshold voltages, and thus, the number of stacked work function layers is effectively reduced. However, the first polarization layer 110 and the second polarization layer 111 in such an approach are formed by modifying the first gate oxide layer 105 and the second gate oxide layer 106, respectively, and the threshold voltage of the formed chemical bonds are relatively small. Thus, the adjustment range of multiple threshold voltages is relatively small, and the problem that different gates have the same threshold voltage is easy to occur, and the performance of the final semiconductor structure is adversely affected.

The present disclosure provides a semiconductor structure and a method for forming the semiconductor structure. A first polarization layer may be formed on the first region, and the material of the first polarization layer may include a semiconductor compound having first polarization atoms. The first polarization atoms in the first polarization layer may directly form a corresponding salt compound with the semiconductor material such that the first polarization layer may have a higher threshold voltage. Accordingly, in a high threshold voltage environment, the adjustment range of each threshold voltage may be increased, the problem that different gates have a same threshold voltage may be reduced, and the performance of the finally formed semiconductor structure may be effectively improved.

To make the above objectives, features, and advantages of the present disclosure more obvious and understandable, specific embodiments of the present disclosure will be described in detail below with reference to the accompanying drawings.

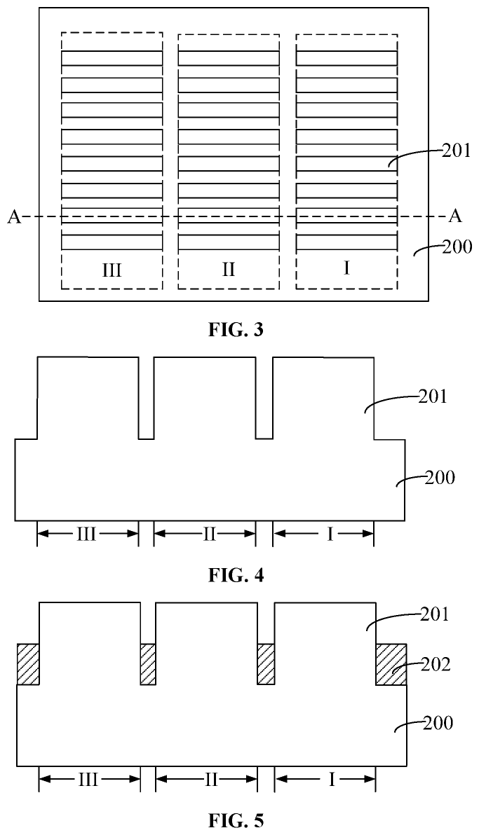

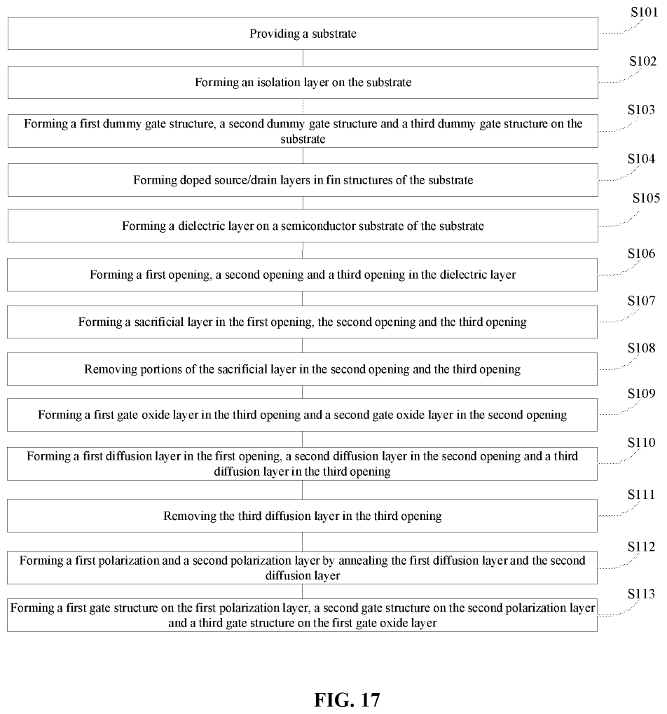

FIG. 17 illustrates an exemplary fabrication process of a semiconductor structure consistent with various disclosed embodiments of the present disclosure. FIGS. 3-16 are schematic structural diagrams of structures corresponding certain stages during the exemplary fabrication process.

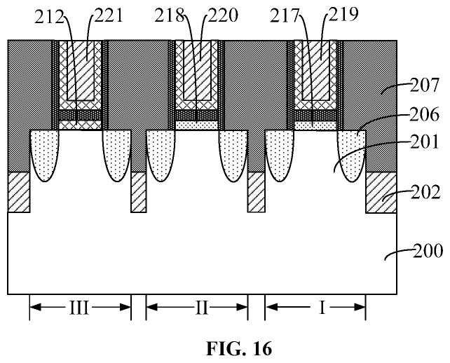

As shown in FIG. 16, at the beginning of the fabrication process, a substrate is provided (S101). FIGS. 3-4 illustrate a corresponding semiconductor structure. FIG. 3 is a top view of the semiconductor structure, and FIG. 4 is a schematic A-A-sectional view of FIG. 3.

As shown in FIGS. 3-4, a substrate is provided. The substrate may include a first region I.

In one embodiment, the substrate may further include a second region II and a third region III, and the second region II may be located between the first region I and the third region III. The first region I, the second region II and the third region III may be used to form transistor structures with different threshold voltages.

In one embodiment, the substrate may include a semiconductor substrate 200 and a plurality of discrete fin structures 201 on the semiconductor substrate 200.

In some embodiments, the fin structures may further include a plurality of channel layers arranged at certain distances along the normal direction of the surface of the semiconductor substrate. In other embodiments, the fin structures may not be provided.

In one embodiment, the method for forming the semiconductor substrate 200 and the fin structures 201 may include providing an initial substrate (not shown) having a mask layer (not shown) exposing portions of the top surface of the initial substrate; and etching the initial substrate using the mask layer as an etching mask to form the semiconductor substrate 200 and the fin structures 201 on the semiconductor substrate 200.

In one embodiment, the material of the semiconductor substrate 200 is silicon. In some embodiments, the material of the semiconductor substrate may also be germanium, silicon germanium, silicon carbide, gallium arsenide, or indium gallium, etc.

In one embodiment, the material of the fin structures 201 is silicon. In some embodiments, the material of the fin structures may also be germanium, silicon germanium, silicon carbide, gallium arsenide, or indium gallium, etc.

Returning to FIG. 17, after providing the substrate, an isolation layer may be formed on the substrate (S102). FIG. 5 illustrates a corresponding structure. The view direction of FIG. 5 is same as the view direction of FIG. 4.

As shown in FIG. 5, an isolation layer 202 may be formed on the semiconductor substrate 200. The isolation layer 202 may cover portions of sidewall surfaces of the fin structures 201. The top surface of the isolation layer 202 may be lower than the top surfaces of the fin structures 201.

In one embodiment, the method for forming the isolation layer 202 may include forming an initial isolation layer (not shown) on the semiconductor substrate 200; etching and removing a portion of the initial isolation layer to form the isolation layer 202. The top surface of the isolation layer 202 may be lower than the top surfaces of the fin structures 201.

The material of the isolation layer 202 may be an insulating material, and the insulating material may include silicon oxide, or silicon oxynitride, etc. In one embodiment, the material of the isolation layer 202 is silicon oxide.

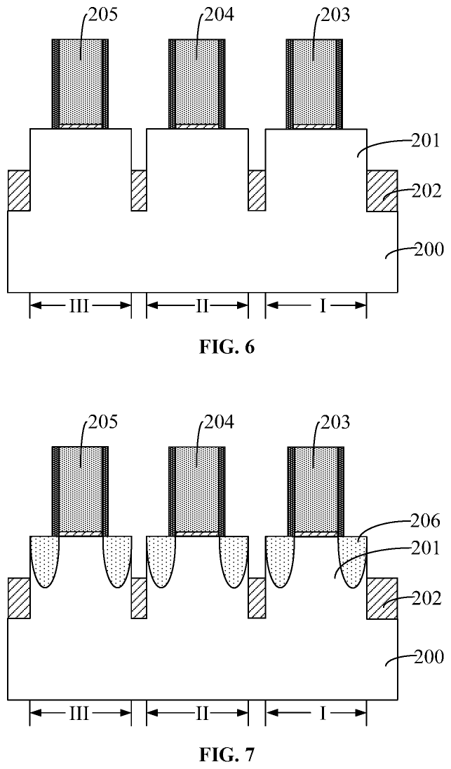

Returning to FIG. 17, after forming the isolation layer, a first dummy gate structure, a second dummy gate structure, and a third dummy gate structure may be formed (S103). FIG. 6 illustrates a corresponding structure.

As shown in FIG. 6, after forming the isolation layer 202, a first dummy gate structure 203, a second dummy gate structure 204, and a third dummy gate structure 205 across the fin structures 201 may be formed on the semiconductor substrate 200. The first dummy gate structure 203 may be formed on the first region I; the second dummy gate structure 204 may be formed on the second region II; and the third dummy gate structure 205 may be formed on the third region III.

It should be noted that, in the drawings, for the convenience of a clear description, the number of dummy gate structures formed on each region is set to one. However, in the actual production process, there may be multiple gate structures formed on each region.

In one embodiment, the method for forming the first dummy gate structure 203 may include forming a first dummy gate dielectric layer on the isolation layer 202; forming a first dummy gate electrode layer on the first dummy gate dielectric layer; forming first sidewall spacers (not labeled) on the sidewall surfaces of the first dummy gate dielectric layer and the first dummy gate electrode layer.

In one embodiment, the material of the first dummy gate dielectric layer is silicon oxide. In some embodiments, the material of the first dummy gate dielectric layer may also be silicon oxynitride. In one embodiment, the material of the first dummy gate electrode layer is silicon.

In one embodiment, the method for forming the second dummy gate structure 204 may include forming a second dummy gate dielectric layer on the isolation layer 202; forming a second dummy gate electrode layer on the second dummy gate dielectric layer; and forming second sidewall spacers (not labeled) on the sidewall surfaces of the second dummy gate dielectric layer and the second dummy gate electrode layer.

In one embodiment, the method for forming the third dummy gate structure 205 may include forming a third dummy gate dielectric layer on the isolation layer; forming a third dummy gate electrode layer on the third dummy gate dielectric layer; and forming third sidewall spacers (not labeled) on the sidewall surfaces of the third dummy gate dielectric layer and the third dummy gate electrode layer.

In one embodiment, the material of the second dummy gate dielectric layer and the third dummy gate dielectric layer is same as the material of the first dummy gate dielectric layer, and the material of the second dummy gate electrode layer and the material of the third dummy gate electrode layer may also be same as the material of the first dummy gate electrode layer.

In one embodiment, the first dummy gate structure 203, the second dummy gate structure 204, and the third dummy gate structure 205 may be formed at the same time; and the production efficiency may be improved.

Returning to FIG. 17, after forming the first dummy gate structure, the second dummy gate structure and the third dummy gate structure, doped source/drain layers may be formed (S104). FIG. 7 illustrates a corresponding structure.

As shown in FIG. 7, after forming the first dummy gate structure 203, the second dummy gate structure 204 and the third dummy gate structure 205, the fin structures 201 may be etched using the first dummy gate structure 203, the second dummy gate structure 204, and the third dummy gate structure 205 as a mask to form a plurality of doped source/drain openings (not labeled) in the fin structures 201; and doped source/drain layers 206 may be formed in the doped source/drain openings.

In one embodiment, the method for forming the doped source/drain layers 206 may include forming an epitaxial layer in the doped source/drain openings by an epitaxial growth process; and in-situ doping the epitaxial layer during the epitaxial growth to dope source/drain ions into the epitaxial layer to form the doped source/drain layers 206.

The source/drain ions may include P-type ions, or N-type ions. In one embodiment, the types of the source/drain ions of the doped source/drain layers 206 formed on the first region, the second region, and third region are different. In some embodiments, the types of source/drain ions of the doped source/drain layers formed on the first region, the second region, and the third region may also be same.

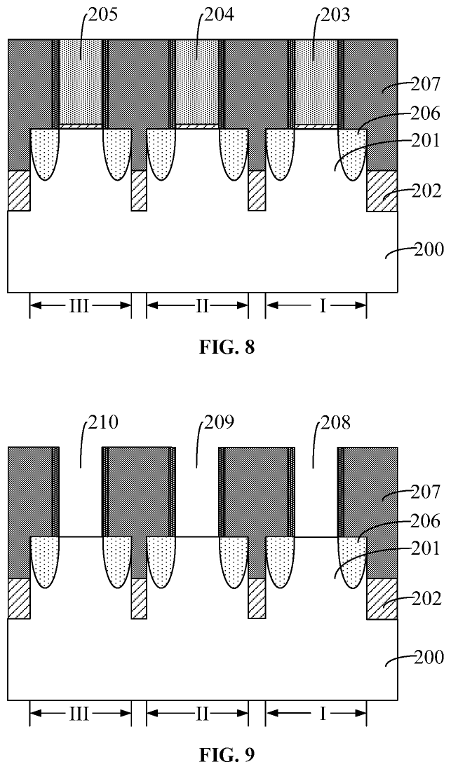

Returning to FIG. 17, after forming the doped source/drain layers, a dielectric layer may be formed on the semiconductor substrate (S105). FIG. 8 illustrates a corresponding structure.

As shown in FIG. 8, after forming the doped source/drain layers 206, a dielectric layer 207 may be formed on the semiconductor substrate 200. The dielectric layer 207 may cover the sidewall surfaces of the first dummy gate structure 203, the second dummy gate structure 204 and the third dummy gate structure 205.

In one embodiment, the material of the dielectric layer 207 is silicon oxide. In some embodiments, the material of the dielectric layer may also be a low-K dielectric material (referring to a dielectric material with a relative dielectric constant lower than 3.9) or an ultra-low-K dielectric material (referring to a dielectric material with a relative dielectric constant of less than 2.5).

Returning to FIG. 17, after forming the dielectric layer, a first opening, a second opening and a third opening may be formed (S106). FIG. 9 illustrates a corresponding structure.

As shown in FIG. 9, after forming the dielectric layer 207, the first dummy gate structure 203 may be removed, and a first opening 208 may be formed in the dielectric layer 207, and the first opening 208 may be formed on the first region I. Further, the second dummy gate structure 204 may be removed, and a second opening 209 may be formed in the dielectric layer 207, and the second opening 209 may be formed on the second region II. Further, the third dummy gate structure 205 may be removed, and a third opening 210 may be formed in the dielectric layer 207, and the third opening 210 may be formed on the third region III.

In one embodiment, the first dummy gate dielectric layer and the first dummy gate electrode layer of the first dummy gate structure 203 may be removed; the second dummy gate dielectric layer and the second dummy gate electrode layer of the second dummy gate structure 204 may be removed; and the third dummy gate dielectric layer and the third dummy gate electrode layer of the third dummy gate structure 205 may be removed.

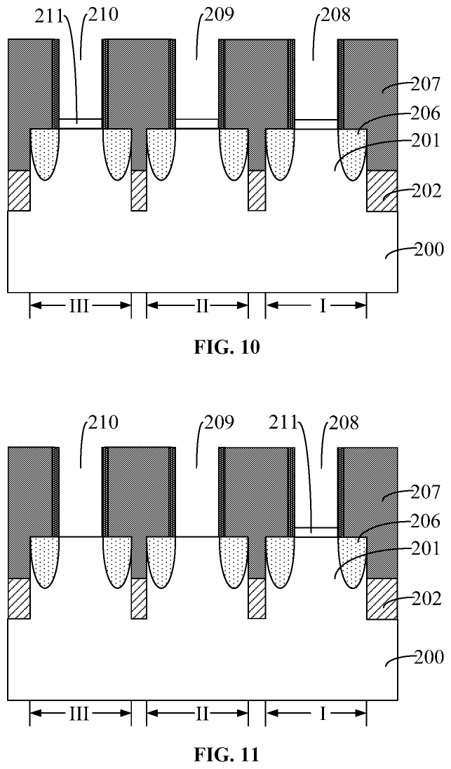

After forming the first opening 208, the second opening 209, and the third opening 210, the method may further include forming a first polarization layer and a first gate structure in the first opening 208. The material of the first polarization layer may be a semiconductor compound material with first polarization atoms. Further, a second polarization layer and a second gate structure may be formed in the second opening 209. The material of the second polarization layer may include the first polarization atoms. Further, a first gate oxide layer and a third gate structure may be formed in the third opening 210. The exemplary fabrication process may be referred to FIGS. 10-16.

Returning to FIG. 17, after forming the first opening, the second opening and the third opening, a sacrificial layer may be formed (S107). FIG. 10 illustrates a corresponding structure.

As shown in FIG. 10, a sacrificial layer 211 may be formed in the first opening 208, the second opening 209, and the third opening 210. The sacrificial layer 211 may cover potions of the sidewall surfaces and top surfaces of the fin structures 201.

In one embodiment, the material of the sacrificial layer 211 is silicon oxide.

Returning to FIG. 17, after forming the sacrificial layer, a portion of the sacrificial layer in the second opening and the third opening may be removed (S108). FIG. 11 illustrates a corresponding structure.

As shown in FIG. 11, a portion of the sacrificial layer 211 located in the second opening 209 and the third opening 210 may be removed.

In one embodiment, a wet etching process is used to remove the portion of the sacrificial layer 211 located in the second opening 209 and the third opening 210. In some embodiments, the portion of the sacrificial layer 211 located in the second opening 209 and the third opening 210 may also be removed by a dry etching process.

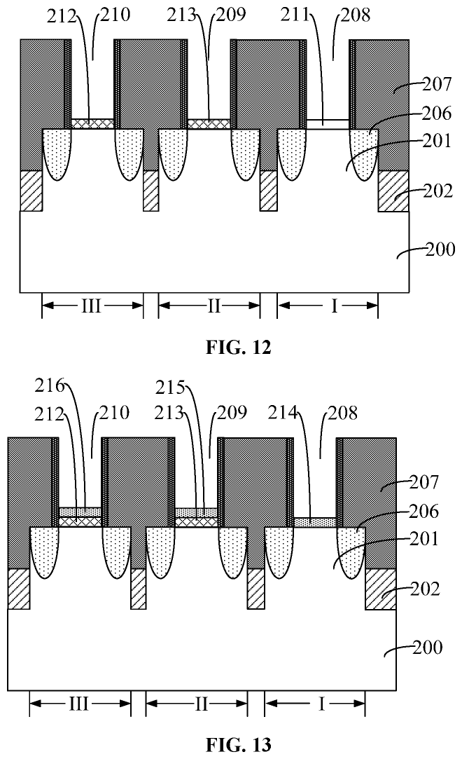

Returning to FIG. 17, after removing the portion of the sacrificial layer in the second opening and the third opening, a first gate oxide layer may be formed in the third opening and a second gate oxide layer may be formed in the second opening (S108). FIG. 12 illustrates a corresponding structure.

As shown in FIG. 12, after removing the portion of the sacrificial layer 211 in the second opening 209 and the third opening 210, a first gate oxide layer 212 may be formed in the third opening 210. The first gate oxide layer 212 may cover portions of the sidewall surfaces and top surfaces of the fin structures 201. Further, a second gate oxide layer 213 may be formed in the second opening 209. The second gate oxide layer 213 may cover portions of the sidewall surfaces and top surfaces of the fin structures 201.

In one embodiment, the material of the first gate oxide layer 212 and the second gate oxide layer 213 is silicon oxide. In one embodiment, the first gate oxide layer 212 and the second gate oxide layer 213 may be formed at the same time.

Returning to FIG. 17, after forming the first gate oxide layer and the second oxide layer, a first diffusion layer, a second diffusion layer and a third diffusion layer may be formed (S109). FIG. 13 illustrates a corresponding structure.

As shown in FIG. 13, after forming the first gate oxide layer 212 and the second gate oxide layer 213, the portion of the sacrificial layer 211 in the first opening 208 may be removed. Further, a first diffusion layer 214 may be formed in the first opening 208. The first diffusion layer 208 may cover portions of the sidewall surfaces and top surfaces of the fin structures 201. Further, a second diffusion layer 215 may be formed in the second opening 209, and the second diffusion layer 215 may be formed on the surface of the second gate oxide layer 213. Further, a third diffusion layer 216 may be formed in the third opening 210, and the third diffusion layer 216 may be formed on the surface of the first gate oxide layer 212.

In one embodiment, the first diffusion layer 214, the second diffusion layer 215, and the third diffusion layer 216 may be formed at the same time, and the materials of the first diffusion layer 214, the second diffusion layer 215 and the third diffusion layer 216 may be lanthanum oxide. In some embodiments, the materials of the first diffusion layer, the second diffusion layer and the third diffusion layer may also be cerium oxide.

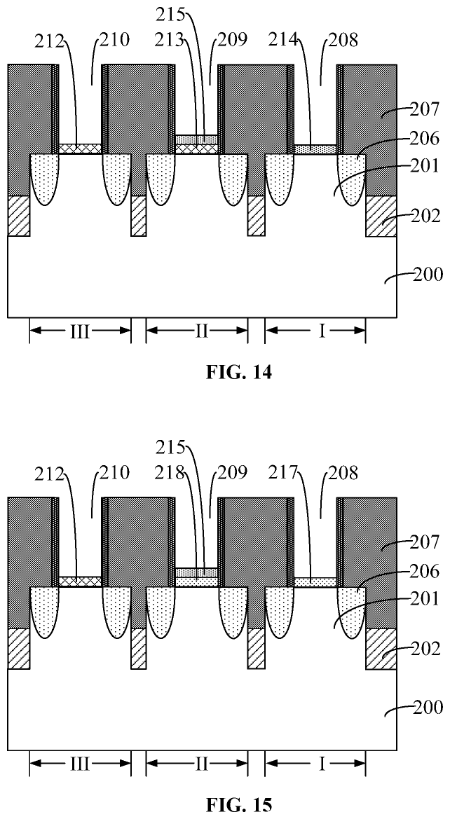

Returning to FIG. 17, after forming the first diffusion layer, the second diffusion layer and the third diffusion layer, the third diffusion layer may be removed (S110). FIG. 14 illustrates a corresponding structure.

As shown in FIG. 14, the third diffusion layer 216 in the third opening 210 may be removed.

In one embodiment, a wet etching process is used to remove the third diffusion layer 216 in the third opening 210. In some embodiments, the process for removing the third diffusion layer 216 in the third opening 210 may include a dry etching process.

Returning to FIG. 17, after removing the third diffusion layer, a first polarization layer and a second polarization layer may be formed (S111). FIG. 15 illustrates a corresponding structure.

As shown FIG. 15, after removing the third diffusion layer 216, the first diffusion layer 214 and the second diffusion layer 215 may be annealed to modify the first diffusion layer 214 into a first polarization layer 217 and modify the second gate oxide layer 213 into a second polarization layer 218.

In one embodiment, the annealing process may cause the first diffusion layer 214 to react with the fin structures 201 to form the first polarization layer 217. The material of the first polarization layer 217 may be a semiconductor compound material with first polarization atoms. By forming a corresponding salt compound using the first polarization atoms in the first polarization layer 217 to react with the semiconductor material, the first polarization layer 217 may have a higher threshold voltage. Accordingly, in a multi-threshold voltage environment, the adjustment range of each threshold voltage may be increased, the problem different gates have a same threshold voltage may be solved, and the performance of the finally formed semiconductor structure may be improved.

Further, the number of stacked layers of the first polarization layer 217 and the subsequently formed first work function layers may be used to jointly adjust the threshold voltages. Thus, the number of stacked layers of the first work function layers may not be the only factor that affects the threshold voltage; and the number of stacked layers of the first work function layer may be effectively reduced.

The material of the first polarization layer 217 may include MₓSi_{y}O_{z}, MₓGe_{y}O_{z}, or MₓSi_{y}Ge_{z}O_{w}, etc., and M is the first polarization atom. In one embodiment, the material of the first polarization layer 217 is lanthanum silicide, lanthanum germanium, or lanthanum silicate (La₂SiO₅, or La₂Si₂O₇), etc.

In one embodiment, through the annealing treatment, the first polarization atoms in the second diffusion layer 215 may be diffused into the second gate oxide layer 213 to form the second polarization layer 218. The number of stacked layers of the second polarization layer 218 and the subsequently formed second work function layers may be used to jointly adjust the threshold voltages. Thus, the number of stacked layers of the second work function layers may not be the only factor that affects the threshold voltage, the number of stacked layers of the second work function layers may be thereby effectively reduced.

In one embodiment, the first polarization atoms are La (lanthanum) atoms. In some embodiments, the first polarization atoms may also be Ce (cerium) atoms, Nb (niobium) atoms, Mg (magnesium) atoms, Sc (scandium) atoms, or Al (aluminum) atoms, etc.

In one embodiment, an atomic concentration of the first polarization atoms in the first polarization layer 217 may be in a range of approximately 2%-30%. In one embodiment, an atomic concentration of the first polarization atoms in the second polarization layer 218 may be less than 1%.

Returning to FIG. 17, after forming the first polarization layer and the second polarization layer, a first gate structure, a second grate structure and a third gate structure may be formed (S112). FIG. 16 illustrates a corresponding structure.

As shown in FIG. 16, after forming the first polarization layer 217 and the second polarization layer 218, the second diffusion layer 215 on the second polarization layer 218 may be removed; and a first gate structure 219 may be formed on the first polarization layer 217. Further, a second gate structure 220 may be formed on the second polarization layer 218; and a third gate structure 221 may be formed on the first gate oxide layer 212.

In one embodiment, the first gate structure 219 may include a first gate dielectric layer on the first polarization layer 217; and a first gate electrode layer (not labeled) on the first gate dielectric layer.

In one embodiment, the first gate structure 219 may further include a first work function layer. The first work function layer may be formed on the first gate dielectric layer, and the first gate electrode layer may be formed on the first work function layer (not labeled).

In one embodiment, the second gate structure 220 may include a second gate dielectric layer on the second polarization layer and a second gate electrode layer (not labeled) on the second gate dielectric layer.

In one embodiment, the second gate structure 220 may further include a second work function layer. The second work function layer may be formed on the second gate dielectric layer, and the second gate electrode layer may be formed on the second work function layer (not labeled).

In one embodiment, the third gate structure 221 may include a third gate dielectric layer on the first gate oxide layer; and a third gate electrode layer (not labeled) on the third gate dielectric layer.

In one embodiment, the third gate structure 221 may further include a third work function layer. The third work function layer may be on the third gate dielectric layer, and the third gate electrode layer may be formed on the third work function layer (not labeled).

In one embodiment, the first gate dielectric layer, the second gate dielectric layer, and the third gate dielectric layer are made of hafnium oxide. In some embodiments, the material of the first gate dielectric layer, the second gate dielectric layer and the third gate dielectric layer may also be lanthanum oxide, or cerium oxide, etc.

Further, the present disclosure provides a semiconductor structure. FIG. 16 illustrates an exemplary semiconductor structure consistent with various disclosed embodiments of the present disclosure.

As shown in FIG. 16, the semiconductor structure includes a substrate. The substrate may include a first region I. The semiconductor structure may also include a first polarization layer 217 formed on the first region I. The material of the first polarization layer 217 may be a semiconductor compound material with first polarization atoms. Further, the semiconductor structure may include a first gate structure 219 formed on the first polarization layer 217.

Because the first polarization atoms in the first polarization layer 217 may directly form a corresponding salt compound with the semiconductor material, the first polarization layer 217 may have a higher threshold voltage. Accordingly, in a multiple-voltage environment, the adjustment range of each threshold voltage may be increased, and the problem that different gate structures have the same threshold voltage may be reduced, and the performance of the final formed semiconductor structure may be effectively improved.

In one embodiment, the first polarization atoms are La (lanthanum) atoms. In some embodiments, the first polarization atoms may also be Ce (cerium) atoms, Nb (niobium) atoms, Mg (magnesium) atoms, Sc (scandium) atoms, or Al (aluminum) atoms.

The material of the first polarization layer 217 may include MₓSi_{y}O_{z}, MₓGe_{y}O_{z}, or MₓSi_{y}Ge_{z}O_{w}. M is the first polarization atom. In one embodiment, the material of the first polarization layer 217 is lanthanum silicide, lanthanum germanide, or lanthanum silicate (La₂SiO₅ or La₂Si₂O₇), etc.

In one embodiment, the substrate may further include a second region II and a third region III. The semiconductor structure may further include a second polarization layer 218 formed on the second region II. The material of the second pole polarization layer 218 may have the first polarization atoms. Further, the semiconductor structure may include a second gate structure 220 on the second polarization layer 218; a first gate oxide layer 212 on the third region III; and a third gate structure 221 on the gate oxide layer 212.

In one embodiment, the semiconductor structure may further include a dielectric layer 207 on the substrate. The dielectric layer 207 may have a first opening 208, a second opening 209, and a third opening 210. The first opening 208 may be located on the first region I; the second opening 209 may be located on the second region II, and the third opening 210 may be located on the third region III. The first polarization layer 217 and the first gate structure 219 may be formed in the first opening 208; the second polarization layer 218 and the second gate structure 220 may be formed in the second opening 209; and the first gate oxide layer 212 and a third gate structure 221 may be formed in the third opening 210.

In one embodiment, the first gate structure 219 may include a first gate dielectric layer on the first polarization layer 217; and a first gate electrode layer on the first gate dielectric layer.

In one embodiment, the first gate structure 219 may further include a first work function layer. The first work function layer may be formed on the first gate dielectric layer, and the first gate electrode layer may be on the first work function layer.

In one embodiment, the second gate structure 220 may include a second gate dielectric layer on the second polarization layer; and a second gate electrode layer on the second gate dielectric layer.

In one embodiment, the second gate structure 220 may further include a second work function layer. The second work function layer may be formed on the second gate dielectric layer, and the second gate electrode layer may be formed on the second work function layer.

In one embodiment, the third gate structure 221 may include a third gate dielectric layer on the first gate oxide layer; and a third gate electrode layer on the third gate dielectric layer.

In one embodiment, the third gate structure 221 may further include a third work function layer. The third work function layer may be formed on the third gate dielectric layer, and the third gate electrode layer may be formed on the third work function layer.

In one embodiment, the material of the first gate dielectric layer may further include lanthanum oxide, cerium oxide, or hafnium oxide, etc.

In one embodiment, the material of the second gate dielectric layer may include lanthanum oxide, cerium oxide, or hafnium oxide, etc.

In one embodiment, the material of the third gate dielectric layer may include lanthanum oxide, cerium oxide, or hafnium oxide, etc.

In one embodiment, an atomic concentration of the first polarization atoms in the first polarization layer 217 may be in a range of approximately 2%-30%.

In one embodiment, an atomic concentration of the first polarization atoms in the second polarization layer 218 may be less than approximately 1%.

Thus, the technical solutions of the present disclosure may have the following advantages.

In the structure of the technical solution of the present disclosure, the material of the first polarization layer located on the first region is a semiconductor compound material with first polarization atoms. The first polarized atoms in the first polarization layer may directly forms a corresponding salt compound with the semiconductor material such that the first polarization layer may have a higher threshold voltage. Thus. in the high threshold voltage environment, the adjustment range of each threshold voltage may be increased, the problem that different gates may have a same threshold voltage may be reduced, and the performance of the finally formed semiconductor structure may be effectively improved.

In the formation method of the technical solution of the present disclosure, a first polarization layer may be formed on the first region, and the material of the first polarization layer may be a semiconductor compound material having first polarization atoms. The first polarization atoms in the first polarized layer may directly form a corresponding salt compound with the semiconductor material such that the first polarization layer may have a higher threshold voltage. Thus, in the high threshold voltage environment, the adjustment range of each threshold voltage may be increased, the problem that different gates have a same threshold voltage may be reduced, and the performance of the finally formed semiconductor structure may be effectively improved.

Although the present disclosure is described as above, the present disclosure is not limited to this. Any person skilled in the art can make various changes and modifications without departing from the spirit and scope of the present disclosure. Therefore, the protection scope of the present disclosure should be subject to the scope defined by the claims.

What is claimed is:

1. A semiconductor structure, comprising:
a substrate including a first region;
a first polarization layer on the first region, wherein a material of the first polarization layer includes a semiconductor compound material containing first polarization atoms; and
a first gate structure on the first polarization layer.

2. The semiconductor structure according to claim 1, wherein:
the first polarization atoms include La atoms, Ce atoms, Nb atoms, Mg atoms, Sc atoms, Al atoms, or a combination thereof.

3. The semiconductor structure according to claim 2, wherein:
the material of the first polarization layer includes MₓSi_{y}O_{z}, MₓGe_{y}O_{z}, MₓSi_{y}G_{z}O_{w}, or a combination thereof, wherein M is a first polarization atom.

4. The semiconductor structure according to claim 2, wherein the substrate further includes a second region and a third region, the semiconductor structure further comprising:
a second polarization layer on the second region, wherein a material of the second polarization layer contains the first polarization atoms;
a second gate structure on the second polarization layer;
a first gate oxide layer on the third region; and
a third gate structure on the first gate oxide layer.

5. The semiconductor structure according to claim 4, further comprising:
a dielectric layer on the substrate,
wherein:
the dielectric layer includes a first opening, a second opening and a third opening;
the first opening is on the first region;
the second opening is on the second region;
the third opening is on the third region;
the first polarization layer and the first gate structure are formed in the first opening;
the second polarization layer and the second gate structure are formed in the second opening; and
the first gate oxide layer and the third gate structure are formed in the third opening.

6. The semiconductor structure according to claim 1, wherein the first gate structure comprises:
a first gate dielectric layer on the first polarization layer; and
a first gate electrode layer on the first gate dielectric layer.

7. The semiconductor structure according to claim 6, wherein the first gate structure further comprises:
a first work function layer, wherein the first work function layer is on the first gate dielectric layer and the first gate electrode layer is on the first work function layer.

8. The semiconductor structure according to claim 4, wherein the second gate structure comprises:
a second gate dielectric layer on the second polarization layer; and
a second gate electrode layer on the second gate dielectric layer.

9. The semiconductor structure according to claim 8, wherein the second gate structure further comprises:
a second work function layer, wherein the second work function layer is on the second gate dielectric layer and the second gate electrode layer is on the second work function layer.

10. The semiconductor structure according to claim 4, wherein the third gate structure comprises:
a third gate dielectric layer on the first gate oxide layer; and
a third gate electrode layer on the third gate dielectric layer.

11. The semiconductor structure according to claim 10, wherein the third gate structure further comprises:
a third work function layer, wherein the third work function layer is on the third gate dielectric layer and the third gate electrode layer is on the third work function layer.

12. The semiconductor structure according to claim 6, wherein:
a material of the first gate dielectric layer includes lanthanum oxide, cerium oxide, hafnium oxide, or a combination thereof.

13. The semiconductor structure according to claim 8, wherein:
a material of the second gate dielectric layer includes lanthanum oxide, cerium oxide, hafnium oxide, or a combination thereof.

14. The semiconductor structure according to claim 10, wherein:
a material of the third gate dielectric layer includes lanthanum oxide, cerium oxide, hafnium oxide, or a combination thereof.

15. The semiconductor structure according to claim 1, wherein:
an atomic concentration of the first polarization atoms in the first polarization layer is in a range of approximately 2%-30%.

16. The semiconductor structure according to claim 4, wherein:
an atomic concentration of the first polarization atoms in the second polarization layer is less than approximately 1%.

17. A method for fabricating a semiconductor structure, comprising:
providing a substrate including a first region;
forming a first polarization layer on the first region, wherein a material of the first polarization layer includes a semiconductor compound material consisting first polarization atoms; and
forming a first gate structure on the first polarization layer.

18. The method according to claim 17, wherein the substrate further includes a second region and a third region, the method further comprising:
forming a dielectric layer on the substrate, wherein the dielectric layer includes a first opening on the first region, a second opening on the second region and a third opening on the third region;
forming the first polarization layer and the first gate structure in the first opening;
forming a second polarization layer and a second gate structure in the second opening; and
forming a third polarization layer and a third gate structure in the third opening.

19. The method according to claim 18, wherein forming the first polarization layer and the second polarization layer comprises:
forming a first diffusion layer on the first region;
forming a second gate oxide layer on the second region;
forming a second diffusion layer on the second gate oxide layer; and
annealing the first diffusion layer and the second diffusion layer to modify the second oxide layer into the second polarization layer and modify the first diffusion layer into the first polarization layer.

20. The method according to claim 17, wherein:
the first gate structure includes a first gate dielectric layer on the first polarization layer and a first gate electrode layer on the first gate dielectric layer.
